(19) United States
(12) Patent Application Publication
(10) Pub. No.: US 2026/0052926 A1
(43) Pub. Date: Feb. 19, 2026

(54) NON-CONTACT SEMICONDUCTOR DIE SINGULATION PROCESS

(71) Applicant: Sandisk Technologies, Inc., Milpitas, CA (US)

(72) Inventors: Minghao Liang, Shanghai (CN); Peng Wang, Shanghai (CN); Zhaoming Kang, Shanghai (CN); Bo Zhai, Shanghai (CN); Dongpeng Xue, Shanghai (CN); Huirong Zhang, Shanghai (CN); Weng Khoon Mong, Penang (MY); Rongkang Zhu, Shanghai (CN)

(21) Appl. No.: 18/806,220

(22) Filed: Aug. 15, 2024

(51) Int. Cl. H01L 21/78; H01L 21/268; H01L 21/683

(52) U.S. Cl. CPC H01L 21/78; H01L 21/268; H01L 21/6836

(57) ABSTRACT

A non-contact semiconductor die singulation process utilizes compressed air to separate a first portion of a semiconductor wafer from a second portion of the semiconductor wafer. During the non-contact semiconductor die singulation process, the semiconductor wafer is placed on dicing tape. A channel is formed along various scribe lines in the semiconductor wafer. When the channels are formed, a compressed air tool applies compressed air along a length of the channel. Pressure from the compressed air causes the semiconductor wafer to deform. As the semiconductor wafer deforms, the semiconductor wafer cracks or splits along the length of the scribe line thereby separating the first portion of the semiconductor wafer from the second portion.

### BACKGROUND

Semiconductor die singulation is a process in which individual semiconductor dies are cut and separated from a semiconductor wafer. For example, the semiconductor wafer is typically mounted on dicing tape (or a die attach film) and a mechanical saw or blade is used to cut the semiconductor wafer along various predefined lines (called scribe lines) that define individual semiconductor dies. However, due to the fragile nature of the semiconductor wafer, one or more surfaces and/or a side wall of each of the individual semiconductor dies may chip or crack during the singulation process.

To reduce the risk of individual semiconductor dies chipping or cracking, a cutting speed of the blade can be reduced. The reduction in the cutting speed reduces blade shaking, which typically causes the semiconductor die to become chipped or cracked. However, if the cutting speed is reduced, the number of semiconductor dies that are singulated within a given time frame is also reduced. Additionally, reducing the cutting speed shortens the life of the blade.

Accordingly, it would be beneficial for a die singulation process to reduce the risk of semiconductor dies chipping or cracking without reducing the number of units that are produced in a given time period.

### SUMMARY

The present application describes a non-contact semiconductor die singulation process. The semiconductor die singulation process described herein reduces the risk of individual semiconductor dies becoming chipped or cracked during a semiconductor die singulation process when compared with current semiconductor die singulation processes.

In an example, the non-contact semiconductor die singulation process uses compressed air to separate individual semiconductor dies from the semiconductor wafer. For example, when semiconductor dies are to be separated from a semiconductor wafer, the semiconductor wafer is attached or adhered to dicing tape (or a die attach film). A laser (or other cutting mechanism) forms a groove or a channel on an exposed surface of the semiconductor wafer. In an example, the groove or channel is formed on and/or over a scribe line of the semiconductor wafer.

When the groove or channel has been formed, compressed air is applied along the groove or the channel. Pressure from the compressed air causes the semiconductor wafer to deform (e.g., deform downward from the exposed surface). As the semiconductor wafer deforms, the semiconductor wafer is split along the channel and the associated scribe line. In an example, expansion properties of the dicing tape, as well as the contactless nature of applying air along the channel and the scribe line, reduces the risk that the semiconductor die will become chipped or cracked. In instances in which chips or cracks do occur, they are smaller in size when compared with the chips or cracks that occur as a result of blade cutting.

Accordingly, examples of the present disclosure describe a method of singulating semiconductor dies from a semiconductor wafer. As will be explained in greater detail, the method includes forming a channel on a scribe line of the semiconductor wafer. In an example, the semiconductor wafer includes a plurality of unsingulated semiconductor dies and the scribe line at least partially defines a boundary of an individual semiconductor die of the plurality of semiconductor dies. Non-contact pressure is applied along the channel to form a crack along the scribe line. The crack at least partially separates the individual semiconductor die from the plurality of semiconductor dies.

Other examples describe a semiconductor die singulation method. The semiconductor die singulation method includes coupling a semiconductor wafer to dicing tape. In an example, the semiconductor wafer includes a plurality of scribe lines. The method also includes removing at least a portion of the semiconductor wafer above at least one scribe line of the plurality of scribe lines. Pressure is then applied to the at least the portion of the semiconductor wafer above the at least one scribe line. The pressure causes a first portion of the semiconductor wafer to separate from a second portion of the semiconductor wafer.

In yet another example, the present disclosure describes forming a channel on a surface of a semiconductor wafer. In an example, the channel is formed over a scribe line of the semiconductor wafer using a channel forming means. Non-contact pressure is then applied along the channel using a pressure application means. In an example, the non-contact pressure causes a first portion of the semiconductor wafer to be separated from a second portion of the semiconductor wafer.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates a semiconductor wafer according to an example.

FIG. 2A illustrates a channel being formed in a semiconductor wafer and having a first shape and/or dimension according to an example.

FIG. 2B illustrates a channel being formed in a semiconductor wafer and having a second shape and/or dimension according to a second example.

FIG. 2C illustrates a channel being formed in a semiconductor wafer and having a third shape and/or dimension according to a third example.

FIG. 3 illustrates a perspective view of a portion of a semiconductor wafer according to an example.

FIG. 4 illustrates how pressure from compressed air, and elastic deformation characteristics of dicing tape, causes a first portion of the semiconductor wafer of FIG. 3 to be separated from a second portion of the semiconductor wafer according to an example.

FIG. 5 illustrates how multiple compressed air tools can be used as part of a non-contact semiconductor die singulation process according to an example.

FIG. 6 illustrates a method for performing a non-contact semiconductor die singulation process according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Individual semiconductor dies are separated from a semiconductor wafer as part of a semiconductor die singulation is a process. The semiconductor die singulation process typically includes mounting the semiconductor wafer on dicing tape. In some examples, a mechanical saw cuts the semiconductor wafer along various scribe lines that define individual semiconductor dies. However, due to the fragile nature of the semiconductor wafer, one or more surfaces and/or side walls of each of the individual semiconductor die may chip or crack during this process.

As previously described, the risk of individual semiconductor dies chipping or cracking can be reduced by slowing or reducing a cutting speed of the blade. However, if the cutting speed is reduced, the number of semiconductor dies that are singulated within a given time frame is also reduced. Additionally, reducing the cutting speed shortens the life of the blade.

To address the above, the present application describes a non-contact semiconductor die singulation process that reduces the risk of individual semiconductor dies becoming chipped or cracked during a semiconductor die singulation process. In an example, the non-contact semiconductor die singulation process uses compressed air to separate individual semiconductor dies from a semiconductor wafer.

For example, when semiconductor dies are to be separated from the semiconductor wafer, the semiconductor wafer is attached or adhered to dicing tape. A laser, or other cutting mechanism, forms a groove or a channel on an exposed surface of the semiconductor wafer. In an example, the groove or channel is formed on and/or over a scribe line of the semiconductor wafer.

When the groove or channel has been formed, compressed air is applied along the channel. Pressure from the compressed air causes the semiconductor wafer to deform (e.g., downward or away from the compressed air). As the semiconductor wafer deforms, the semiconductor wafer is split along the channel and the associated scribe line. In an example, expansion properties of the dicing tape, as well as the contactless nature of applying compressed air along the channel and the scribe line, reduces the risk that the semiconductor dies will become chipped or cracked. In instances in which chips or cracks do occur, they are smaller in size when compared with the chips or cracks that occur as a result of blade cutting.

Accordingly, many technical benefits may be realized including, but not limited to, reducing the number and/or size of chips or cracks in semiconductor dies when compared with current semiconductor die singulation processes thereby increasing the reliability of the semiconductor die; increasing the number of units that are produced during a particular time frame when compared with current semiconductor die singulation processes; and reducing the occurrence burr generation that occurs during current semiconductor die singulation processes.

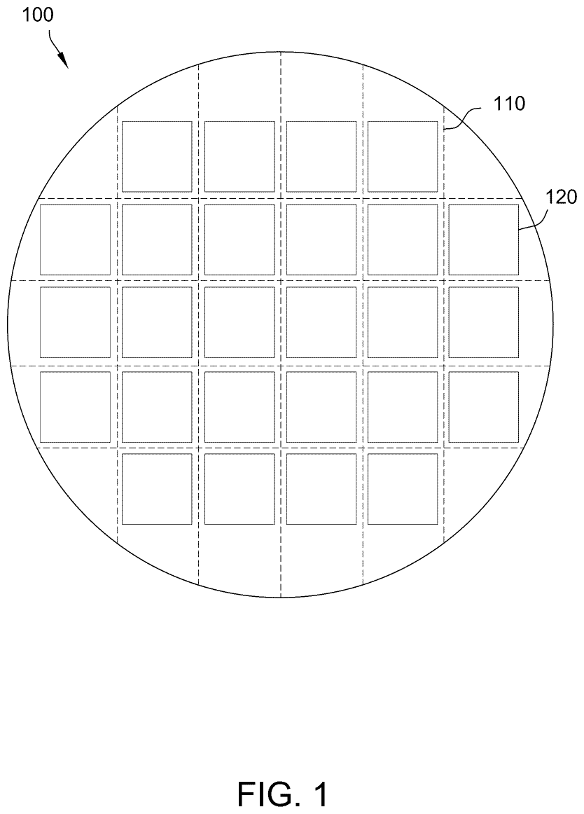

These and other examples will be shown and described in greater detail with respect to FIG. 1-FIG. 6.

FIG. 1 illustrates a semiconductor wafer 100 according to an example. In an example, the semiconductor wafer 100 includes a number of semiconductor dies 120. The semiconductor dies 120 are fabricated using any suitable fabrication process. Additionally, the semiconductor dies 120 may have any desired shape and/or size.

As also shown in FIG. 1, the semiconductor wafer 100 includes a number of scribe lines 110. In an example, the scribe lines 110 are arranged in a grid and define one or more boundaries of each semiconductor die 120. For example, during the singulation process described herein, each semiconductor die 120 will be separated from the semiconductor wafer 100, and from other semiconductor dies 120, based on a cut and/or a crack that will be formed along each scribe line 110.

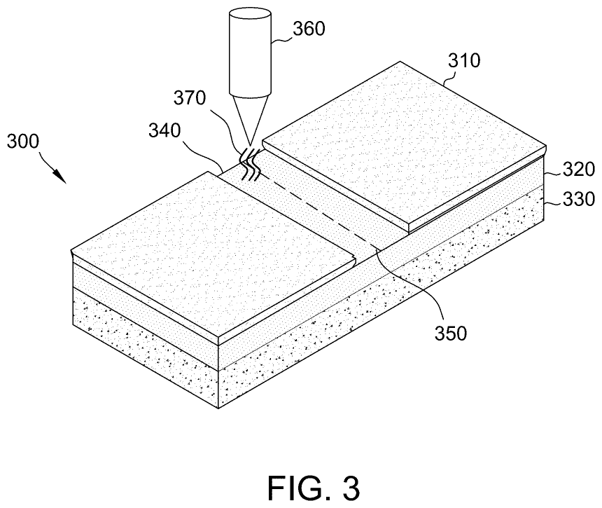

In an example and as will be described in greater detail herein, when the semiconductor wafer 100 and/or the semiconductor dies 120 have been fabricated, the semiconductor wafer 100 is positioned on and/or adhered to dicing tape (e.g., dicing tape 330 (FIG. 3) or a die attach film). When the semiconductor wafer 100 has been adhered to the dicing tape, a cutting mechanism is used to form a channel on and/or over each scribe line 110. In an example, the cutting mechanism is a laser. In another example, the cutting mechanism is a saw. Although a laser and a saw are specifically mentioned, channel may be formed by any suitable means.

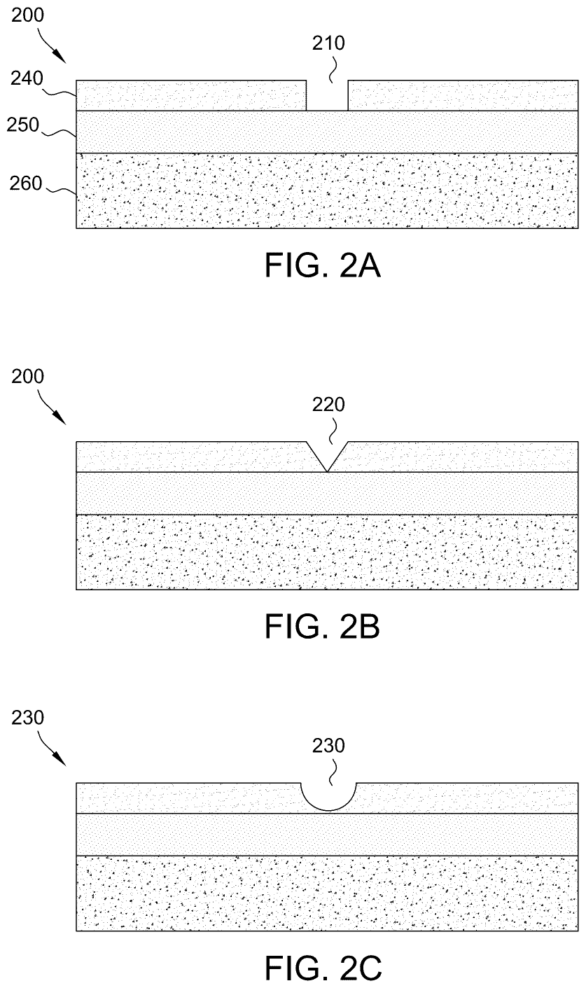

In an example, the channel may have any shape, depth and/or width. For example and referring to FIG. 2A, FIG. 2A illustrates a channel 210 being formed in a semiconductor wafer 200 and having a first shape and/or dimension according to a first example. In an example, the semiconductor wafer 200 is similar to the semiconductor wafer 100 shown and described with respect to FIG. 1. For example, the semiconductor wafer 200 includes a first layer 240 (or a metal layer) and a second layer 250 (or a silicon layer). In an example, the first layer 240 and the second layer 250 are provided on dicing tape 260.

In the example shown in FIG. 2A, the channel 210 is square shaped and has a depth that is equivalent to, or is substantially equivalent to, a thickness of the first layer 240. For example, if the first layer 240 has a thickness of seven micrometers, the depth of the channel 240 is seven micrometers.

FIG. 2B illustrates a channel 220 being formed in a semiconductor wafer 200 and having a second shape and/or dimension according to a second example. In the example shown in FIG. 2B, the channel 220 is triangular shaped or shaped like a “V”. FIG. 2C illustrates a channel 230 being formed in a semiconductor wafer 200 and having a third shape and/or dimension according to a third example. In the example shown in FIG. 2C, the channel 230 is rounded. Although various shapes and dimensions are shown, the channel may have any shape and/or dimension.

For example and as shown in FIG. 2A-FIG. 2C, the channel does not extend entirely through the semiconductor wafer 200. For example, the cutting mechanism causes the channel to be formed in or on a first surface (e.g., a metal surface) of the semiconductor wafer 200 along each scribe line (e.g., scribe line 110 (FIG. 1)). When the channel has been formed, a compressed air tool (or a non-contact cutting apparatus) applies compressed air along the channel.

Referring back to FIG. 1, the compressed air, along with elastic deformation characteristics of the dicing tape, causes the semiconductor wafer 100 to bend. As the semiconductor wafer 100 bends, cracks will form along the scribe line 110 on which the compressed air is applied. In an example, the cracks will propagate along the entire length of the scribe line 110 thereby separating at least a portion of the semiconductor die from another portion of the semiconductor die 100. This process is repeated along each channel associated with each scribe line 110 until individual semiconductor dies 120 have been separated from the semiconductor wafer 100.

In an example, use of the compressed air enables the propagation of the crack along the scribe line 110 to be controlled. For example, the amount of pressure provided by the compressed air and/or a movement speed of the compressed air tool along the surface of the semiconductor wafer 100 may be controlled or altered to reduce the risk that chips will form during the non-contact semiconductor die singulation process. As a result, backside and/or sidewall chipping will be reduced or eliminated when compared with current semiconductor die singulation processes in which a blade is used.

FIG. 3 illustrates a perspective view of a portion of a semiconductor wafer 300 according to an example. In an example, the portion of the semiconductor wafer 300 is part of the semiconductor wafer 100 shown and described with respect to FIG. 1.

In this example, the semiconductor wafer 300 includes a first layer 310 provided on or over a silicon layer 320. In an example, the first layer 310 is a metal layer. Although a first layer 310 is specifically shown and described, the semiconductor wafer 300 may include any number of layers as a result of a semiconductor wafer fabrication process.

As shown in FIG. 3, a channel 340 has been formed in the first layer 310. In an example, the channel 340 is formed by a laser. In another example, the channel 340 is formed by a saw. Although a laser and a saw are specifically mentioned, the channel 340 may be formed by any other process or mechanism. For example, the channel 340 may be formed during a semiconductor wafer fabrication process. Regardless of how the channel 340 is formed, in an example, the channel 340 is formed on, over, or is otherwise associated with a scribe line 350.

In an example, when the channel 340 has been formed, a compressed air tool 360 moves along the channel 340 and applies compressed air 370 to the channel 340 and the associated scribe line 350. In an example, the amount of pressure applied by the compressed air 370 on the channel 340 can vary. For example, the amount of pressure applied by the compressed air 370 is based, at least in part, on a thickness of the semiconductor wafer 300. In another example, the amount of pressure applied by the compressed air 370 is based, at least in part, on a depth of the channel 340. In yet another example, the amount of pressure applied by the compressed air 370 is based, at least in part, on a movement speed of the compressed air tool 360 and/or a location of the compressed air tool 360.

The movement speed of the compressed air tool 360 and/or the amount of pressure applied by the compressed air 370 may also vary based, at least in part, on a number of semiconductor dies that have been singulated from the semiconductor wafer 300. For example, during an initial pass, the compressed air tool 360 may cause a first amount of pressure to be applied to the semiconductor wafer 300 and/or the compressed air tool 360 may move at a first speed. However, during a second pass, or a pass in which an individual semiconductor die is to be separated from the semiconductor wafer 300, the compressed air tool 360 may cause a second amount of pressure to be applied to the semiconductor wafer and/or the compressed air tool 360 may move at a second speed.

The pressure from the compressed air 370, and the elastic deformation characteristics of the dicing tape 330, causes the semiconductor wafer 300 to deform or bend (e.g., downward). As the semiconductor wafer 300 deforms, cracks form along the scribe line 350. In an example, the crack will propagate along the entire length of the scribe line 350 thereby separating a first portion of the semiconductor wafer 300 from a second portion of the semiconductor wafer 300.

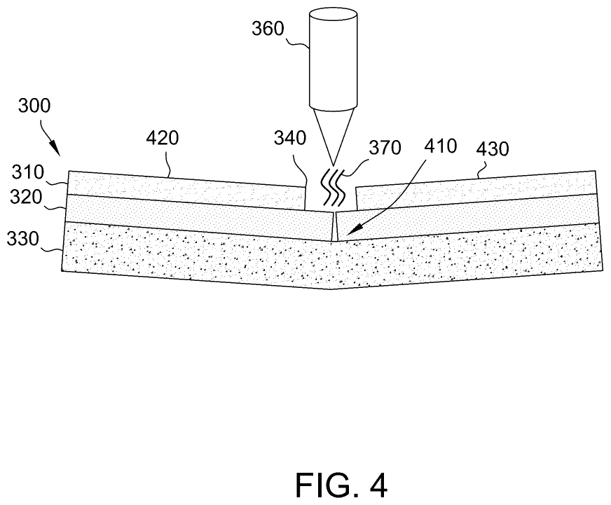

For example and referring to FIG. 4, FIG. 4 illustrates how pressure from compressed air 370, and elastic deformation characteristics of dicing tape 330, causes a first portion 420 of the semiconductor wafer 300 of FIG. 3 to be separated from a second portion 430 of the semiconductor wafer 300 according to an example. As shown in FIG. 4, when the channel 340 has been provided in the semiconductor wafer 300 and when compressed air 370 is applied to the channel 340 by the compressed air tool 360, the pressure applied by the compressed air 370 causes the semiconductor wafer 300 to bend or deform. As the semiconductor wafer 300 bends or deforms, elastic deformation characteristics of the dicing tape 330 enable the dicing tape 330 to bend with the semiconductor wafer 300.

Additionally, as the semiconductor wafer 300 bends, a crack 410 is formed along the scribe line associated with the channel 340. As a result, the first portion 420 of the semiconductor wafer is separated from a second portion 430 of the semiconductor wafer 300. This process can be repeated to separate each semiconductor die in the semiconductor wafer 300 from other semiconductor dies.

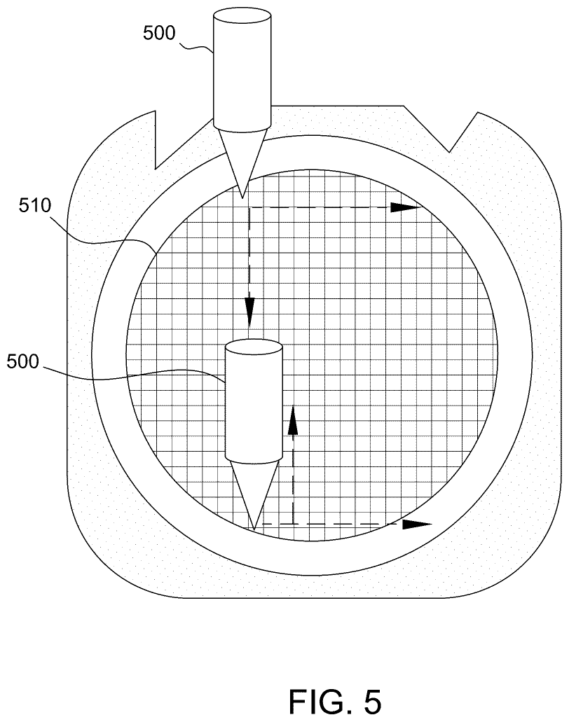

FIG. 5 illustrates how multiple compressed air tools 500 can be used as part of a non-contact semiconductor die singulation process according to an example. For example, once the various channels have been formed on a semiconductor wafer 510, a first compressed air tool may be positioned at a first location on the semiconductor wafer 510 and a second compressed air tool may be positioned at a second location on the semiconductor wafer 510.

Each compressed air tool 500 moves over an exposed surface of the semiconductor wafer 510 simultaneously. For example, the first compressed air tool moves from the first location in a first direction (e.g., indicated by at least one of the dashed arrows) along each channel and/or scribe line. Likewise, the second compressed air tool moves from the second location in the first direction or a second direction. As each compressed air tool moves along the various channels and scribe lines, portions of the semiconductor wafer 510 are separated from other portions such as previously described.

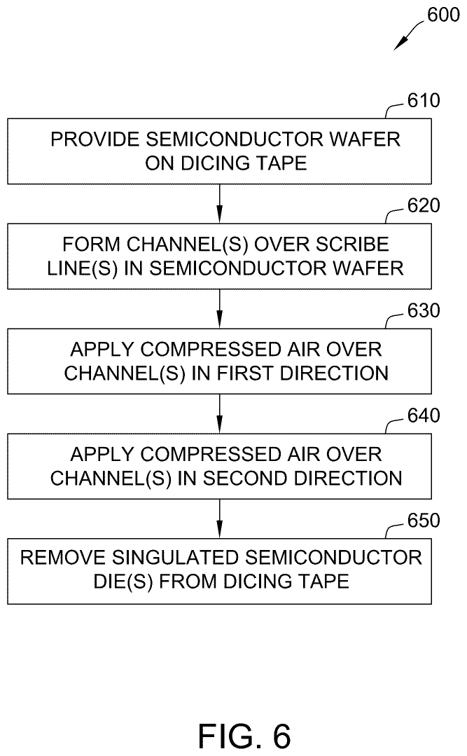

FIG. 6 illustrates a method 600 for performing a non-contact semiconductor die singulation process according to an example. In an example, the method 600 may be used to separate a first portion of a semiconductor wafer from a second portion of the semiconductor wafer such as described herein.

In an example, the method 600 begins when a semiconductor wafer is provided on (610), or otherwise adhered to, dicing tape. The semiconductor wafer is applied to the dicing tape by any suitable means.

When the semiconductor wafer has been applied to the dicing tape, one or more channels are formed (620) over one or more scribe lines of the semiconductor wafer. In an example, the channels are formed on an exposed surface of the semiconductor wafer and are used to remove one or more layers of the semiconductor wafer. In an example, a laser is used to form the one or more channels. In another example, a saw or blade is used to form the one or more channels.

When at least one of the channels has been formed, a compressed air tool is positioned over the at least one channel and applies (630) compressed air along the channel in a first direction. In an example, the pressure from the compressed air, along with the elastic deformation properties of the dicing tape, cause the semiconductor wafer to bend and subsequently crack along the scribe line, thereby separating at least one portion of the semiconductor wafer from a second portion of the semiconductor wafer. This process may be repeated a number of different times.

Additionally, the compressed air tool (or another compressed air tool) is positioned over at least one channel and applies (640) compressed air along the channel in a second direction. The pressure from the compressed air, along with the elastic deformation properties of the dicing tape, cause the semiconductor wafer to bend and subsequently crack along the scribe line. As a result, individual semiconductor dies are singulated from the semiconductor wafer. As with operation 630, operation 640 may be repeated any number of times.

When an individual semiconductor die has been singulated from the semiconductor wafer, the semiconductor die is removed (650) from the dicing tape. In an example, operation 650 occurs after all semiconductor dies have been singulated from the semiconductor wafer. In another example, operation 650 may occur at various times during the non-contact semiconductor die singulation process.

Based on the above, examples of the present disclosure describe a method of singulating semiconductor dies from a semiconductor wafer, comprising: forming a channel on a scribe line of the semiconductor wafer, the semiconductor wafer including a plurality of unsingulated semiconductor dies and the scribe line at least partially defining a boundary of an individual semiconductor die of the plurality of semiconductor dies; and applying non-contact pressure along the channel to form a crack along the scribe line, the crack at least partially separating the individual semiconductor die from the plurality of semiconductor dies. In an example, the channel is formed by a laser. In an example, the non-contact pressure is applied using compressed air. In an example, the semiconductor wafer is attached to dicing tape. In an example, the non-contact pressure and deformation characteristics of the dicing tape causes the crack to form along the scribe line. In an example, the method also includes removing the individual semiconductor die from the dicing tape. In an example, the non-contact pressure is a first non-contact pressure and is applied at a first location on the wafer and wherein the method further comprises applying second non-pressure at a second location on the wafer.

Examples also describe a semiconductor die singulation method, comprising: coupling a semiconductor wafer to dicing tape, the semiconductor wafer comprising a plurality of scribe lines; removing at least a portion of the semiconductor wafer above at least one scribe line of the plurality of scribe lines; and applying pressure to the at least the portion of the semiconductor wafer above the at least one scribe line to separate a first portion of the semiconductor wafer from a second portion of the semiconductor wafer. In an example, the pressure is non-contact pressure. In an example, the non-contact pressure is applied using compressed air. In an example, the at least the portion of the semiconductor wafer that is removed is removed by a laser. In an example, the at least the portion of the semiconductor wafer that is removed is removed by a blade. In an example, the method also includes applying pressure to another portion of the semiconductor wafer above at least another scribe line to separate a third portion of the semiconductor wafer from at least one of the first portion of the semiconductor wafer and the second portion of the semiconductor wafer. In an example, the method also includes removing the third portion of the semiconductor wafer from the dicing tape.

Additional examples describe a method, comprising: forming a channel on a surface of a semiconductor wafer, the channel being formed over a scribe line of the semiconductor wafer using a channel forming means; and applying non-contact pressure along the channel using a pressure application means, the non-contact pressure causing a first portion of the semiconductor wafer to be separated from a second portion of the semiconductor wafer. In an example, the channel forming means is a laser. In an example, the channel forming means is a blade. In an example, the pressure application means is compressed air. In an example, the method also includes coupling the semiconductor wafer to a wafer securement means. In an example, the non-contact pressure is a first non-contact pressure and the pressure application means is a first pressure application means and wherein the method further comprises applying a second non-contact pressure using a second pressure application means, wherein the first non-contact pressure and the second non-contact pressure are applied to the semiconductor wafer simultaneously.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method of singulating semiconductor dies from a semiconductor wafer, comprising:
forming a channel on a scribe line of the semiconductor wafer, the semiconductor wafer including a plurality of unsingulated semiconductor dies and the scribe line at least partially defining a boundary of an individual semiconductor die of the plurality of semiconductor dies; and
applying non-contact pressure along the channel to form a crack along the scribe line, the crack at least partially separating the individual semiconductor die from the plurality of semiconductor dies.

2. The method of claim 1, wherein the channel is formed by a laser.

3. The method of claim 1, wherein the non-contact pressure is applied using compressed air.

4. The method of claim 1, wherein the semiconductor wafer is attached to dicing tape.

5. The method of claim 4, wherein the non-contact pressure and deformation characteristics of the dicing tape causes the crack to form along the scribe line.

6. The method of claim 4, further comprising removing the individual semiconductor die from the dicing tape.

7. The method of claim 1, wherein the non-contact pressure is a first non-contact pressure and is applied at a first location on the wafer and wherein the method further comprises applying second non-pressure at a second location on the wafer.

8. A semiconductor die singulation method, comprising:
coupling a semiconductor wafer to dicing tape, the semiconductor wafer comprising a plurality of scribe lines;
removing at least a portion of the semiconductor wafer above at least one scribe line of the plurality of scribe lines; and
applying pressure to the at least the portion of the semiconductor wafer above the at least one scribe line to separate a first portion of the semiconductor wafer from a second portion of the semiconductor wafer.

9. The method of claim 8, wherein the pressure is non-contact pressure.

10. The method of claim 9, wherein the non-contact pressure is applied using compressed air.

11. The method of claim 8, wherein the at least the portion of the semiconductor wafer that is removed is removed by a laser.

12. The method of claim 8, wherein the at least the portion of the semiconductor wafer that is removed is removed by a blade.

13. The method of claim 8, further comprising applying pressure to another portion of the semiconductor wafer above at least another scribe line to separate a third portion of the semiconductor wafer from at least one of the first portion of the semiconductor wafer and the second portion of the semiconductor wafer.

14. The method of claim 13, further comprising removing the third portion of the semiconductor wafer from the dicing tape.

15. A method, comprising:
forming a channel on a surface of a semiconductor wafer, the channel being formed over a scribe line of the semiconductor wafer using a channel forming means; and
applying non-contact pressure along the channel using a pressure application means, the non-contact pressure causing a first portion of the semiconductor wafer to be separated from a second portion of the semiconductor wafer.

16. The method of claim 15, wherein the channel forming means is a laser.

17. The method of claim 15, wherein the channel forming means is a blade.

18. The method of claim 15, wherein the pressure application means is compressed air.

19. The method of claim 15, further comprising coupling the semiconductor wafer to a wafer securement means.

20. The method of claim 15, wherein the non-contact pressure is a first non-contact pressure and the pressure application means is a first pressure application means and wherein the method further comprises applying a second non-contact pressure using a second pressure application means, wherein the first non-contact pressure and the second non-contact pressure are applied to the semiconductor wafer simultaneously.
